(19) United States
(12) Patent Application Publication
(10) Pub. No.: US 2025/0316605 A1
(43) Pub. Date: Oct. 9, 2025

(54) INTERCONNECT INCLUDING CONDUCTOR IN PHOTO-IMAGEABLE DIELECTRIC LAYER

(71) Applicant: QUALCOMM Incorporated, San Diego, CA (US)

(72) Inventor: Heun Gun SHIN, San Diego, CA (US)

(21) Appl. No.: 18/630,304

(22) Filed: Apr. 9, 2024

(51) Int. Cl. H01L 23/538; H01L 21/48

(52) U.S. Cl. CPC H01L 23/5386; H01L 21/4857; H01L 23/5383

(57) ABSTRACT

A device includes a substrate that includes a photo-imageable dielectric (PID) layer having a layer surface and multiple sidewalls extending from an opening in the layer surface to define a trench. The substrate also includes a conductive interconnect configured to form at least a portion of a conductive path of the substrate. The conductive interconnect includes an embedded conductor within the trench. The conductive interconnect also includes a metal trace on the layer surface and electrically connected to the embedded conductor.

### FIELD

Various features relate to integrated circuit devices.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. In some circumstances, via stitching can be used to improve device performance. To illustrate, traces can be formed in parallel on multiple interconnect layers and electrically connected to each other using a series of vias between the traces, which increases the effective conductive cross-section of a conductive path along the traces. The larger effective conductive cross-section provides lower resistance along the conductive path and also enables higher thermal dissipation. However, via stitching increases manufacturing complexity and also reduces the amount of usable area on the multiple interconnect levels, and thus reduces design flexibility for other electrical connections.

### SUMMARY

Various features relate to integrated circuit devices.

One example provides a device that includes a substrate that includes a photo-imageable dielectric (PID) layer having a layer surface and multiple sidewalls extending from an opening in the layer surface to define a trench. The substrate also includes a conductive interconnect configured to form at least a portion of a conductive path of the substrate. The conductive interconnect includes an embedded conductor within the trench. The conductive interconnect also includes a metal trace on the layer surface and electrically connected to the embedded conductor.

Another example provides a method of fabrication that includes forming a trench in a layer surface of a photo-imageable dielectric (PID) layer of a substrate. The method includes forming, within the trench, an embedded conductor of a conductive interconnect that forms at least a portion of a conductive path of the substrate. The method also includes forming a metal trace on the layer surface and electrically coupled to the embedded conductor.

Another example provides a device that includes a substrate that includes a photo-imageable dielectric (PID) layer having a layer surface and multiple sidewalls extending from an opening in the layer surface to define a trench. The substrate also includes a conductive interconnect configured to form at least a portion of a conductive path of the substrate. The conductive interconnect includes an embedded conductor within the trench. The conductive interconnect also includes a metal trace on the layer surface and electrically connected to the embedded conductor. The device also includes an electronic device electrically coupled to the conductive interconnect.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a cross-sectional view of an exemplary device having an interconnect that includes an embedded conductor within a PID layer.

FIG. 1B illustrates an exploded view of the exemplary device of FIG. 1A.

FIG. 2A illustrates a cross-sectional view of a particular implementation of an exemplary device having an interconnect that includes an embedded conductor within a PID layer, where a thickness of the embedded conductor matches a thickness of the PID layer.

FIG. 2B illustrates a cross-sectional view of another particular implementation of an exemplary device having an interconnect that includes an embedded conductor extending across multiple PID layers.

FIG. 3A illustrates a cross-sectional view of another particular implementation of an exemplary device having an interconnect that includes an embedded conductor within a PID layer.

FIG. 3B illustrates a cross-sectional view of another particular implementation of an exemplary device having an interconnect that includes embedded conductors within multiple PID layers.

FIG. 4A illustrates a cross-sectional view of a particular implementation of an exemplary device having an interconnect that includes an embedded conductor within a PID layer, where a thickness of the embedded conductor is less than a thickness of the PID layer.

FIG. 4B illustrates a cross-sectional view of another particular implementation of an exemplary device having an interconnect that includes an embedded conductor extending across a PID layer and through a portion of another PID layer.

FIG. 5 illustrates a cross-sectional profile view of an exemplary device having an interconnect that includes an embedded conductor within a PID layer.

FIG. 6A illustrates a first exemplary sequence for fabricating an exemplary device having an interconnect that includes an embedded conductor within a PID layer.

FIG. 6B illustrates a second exemplary sequence for fabricating an exemplary device having an interconnect that includes an embedded conductor within a PID layer.

FIG. 7 illustrates an exemplary flow diagram of a method of semiconductor fabrication for a device having an interconnect that includes an embedded conductor within a PID layer.

FIG. 8 illustrates various electronic devices that may integrate an exemplary interconnect that includes an embedded conductor within a PID layer as described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art mobile application devices demand a small form factor, low cost, a tight power budget, and high electrical performance. Mobile package design has evolved to meet these divergent goals for enabling mobile applications that support multimedia enhancements. For example, fan-out (FO) wafer level packaging (WLP) or FO-WLP process technology is a development in packaging technology that is useful for mobile applications. This chip first FO-WLP process technology solution provides flexibility to fan-in and fan-out connections from a die to package balls. In addition, this solution also provides a height reduction of a first level interconnect between the die and the package balls of mobile application devices. These mobile applications, however, are susceptible to power and signal routing issues when multiple dies are arranged within the small form factor.

Stacked die schemes and chiplet architectures are becoming more common as significant power performance area (PPA) yield enhancements are demonstrated for stacked die and chiplet architecture product lines. As used herein, “stacked dies” and/or “stacked ICs” refer to arrangements in which one die (e.g., a first die) is disposed over (including directly over) another die (e.g., a second die). Unfortunately, although interconnect resistance and thermal dissipation issues associated with such architectures can be at least partially addressed using via stitching, via stitching also increases manufacturing complexity and reduces the amount of usable area on multiple interconnect levels, and thus reduces design flexibility for other electrical connections.

Aspects of the present disclosure are directed to an interconnect that includes an embedded conductor within a PID layer, which can provide improved performance with improved design flexibility and reduced manufacturing complexity as compared to via stitching. In contrast to via stitching, in which the conductive lines and connecting vias are built up over multiple layers to form a trace that may span two, three, or more metal layers (e.g., metal layers M1, M2, and M3), aspects of the present disclosure include forming a trench in a PID layer and filling the trench with an embedded conductor, which is electrically coupled to a metal trace above the trench. According to some aspects, the depth of the trench in the PID layer is controlled to generate a depth controlled embedded pattern. As a result of using the embedded conductor, an interconnect having comparable, or improved, resistance and thermal dissipation properties is formed at a single metal layer (e.g., M1), which improves design flexibility for traces at other metal layers, as compared to conventional via stitching.

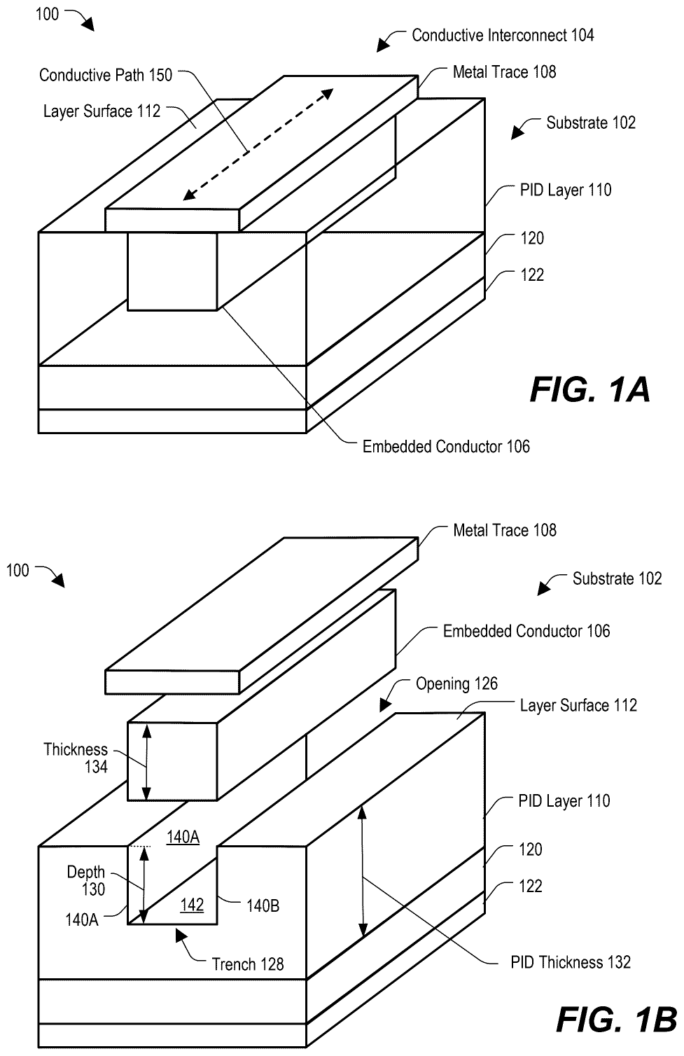

In some drawings, multiple instances of a particular type of feature are used. Although these features are physically and/or logically distinct, the same reference number is used for each, and the different instances are distinguished by addition of a letter to the reference number. When the features as a group or a type are referred to herein e.g., when no particular one of the features is being referenced, the reference number is used without a distinguishing letter. However, when one particular feature of multiple features of the same type is referred to herein, the reference number is used with the distinguishing letter. For example, referring to FIG. 1B, multiple sidewalls of a trench are illustrated and associated with reference numbers 140A and 140B. When referring to a particular one of these sidewalls, such as a sidewall 140A, the distinguishing letter “A” is used. However, when referring to any arbitrary one of these sidewalls or to these sidewalls as a group, the reference number 140 is used without a distinguishing letter.

Exemplary Device and Implementations Having an Interconnect that Includes an Embedded Conductor within a PID Layer

FIG. 1A illustrates a cross-sectional view of an exemplary device having an interconnect that includes an embedded conductor within a PID layer. FIG. 1B illustrates an exploded view of the exemplary device of FIG. 1A.

The device 100 includes a substrate 102, a portion of which is depicted in FIGS. 1A and 1B. As illustrated, the substrate 102 includes a PID layer 110 having a layer surface 112 and multiple sidewalls 140, illustrated as a first sidewall 140A and a second sidewall 140B opposite the first sidewall 140A, that extend from an opening 126 in the layer surface 112 to define a trench 128. The PID layer 110 is on a layer 120, such as a dielectric layer, that is above a layer 122 (e.g., a core layer of the substrate 102).

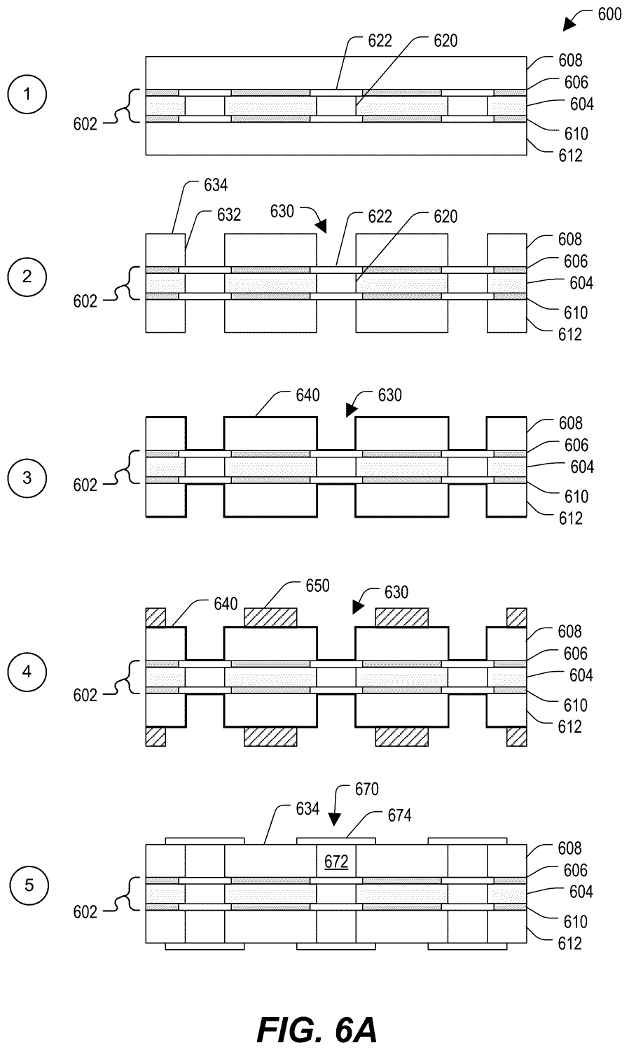

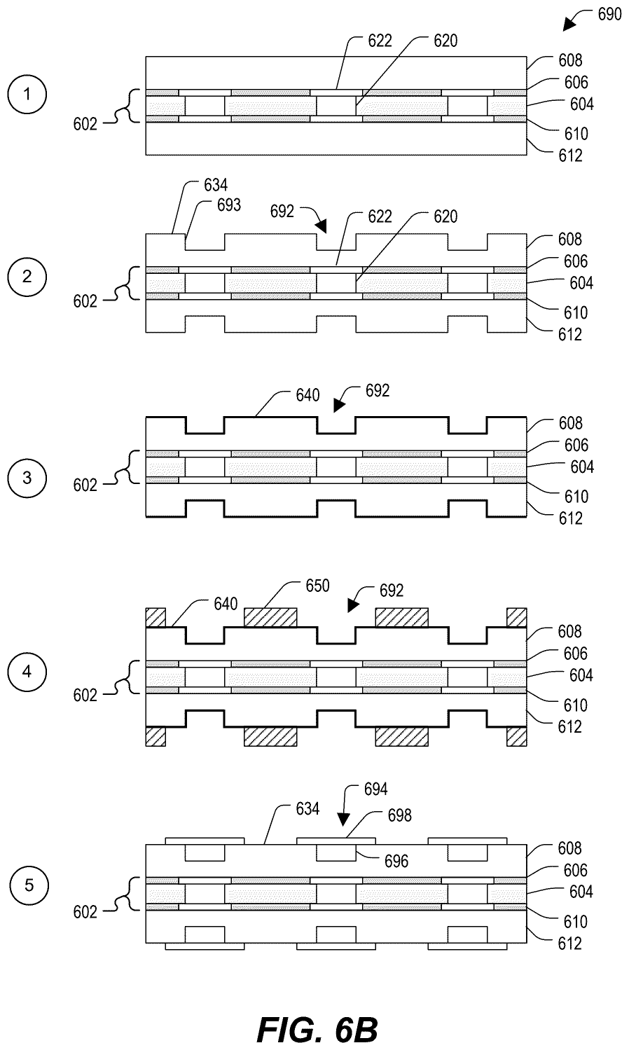

The substrate 102 also includes a conductive interconnect 104 that is configured to form at least a portion of a conductive path 150 of the substrate 102. The conductive interconnect 104 includes an embedded conductor 106 within the trench 128. According to an aspect, the embedded conductor 106 is a metal, such as copper, that is applied to fill the trench 128 using a via fill plating process, as described further with reference to FIGS. 6A-B. The conductive interconnect 104 also includes a metal trace 108 that is on the layer surface 112 and electrically connected to the embedded conductor 106. In an illustrative example, the metal trace 108 is one of multiple metal traces of a first metal layer (e.g., an M1 layer) of the substrate 102.

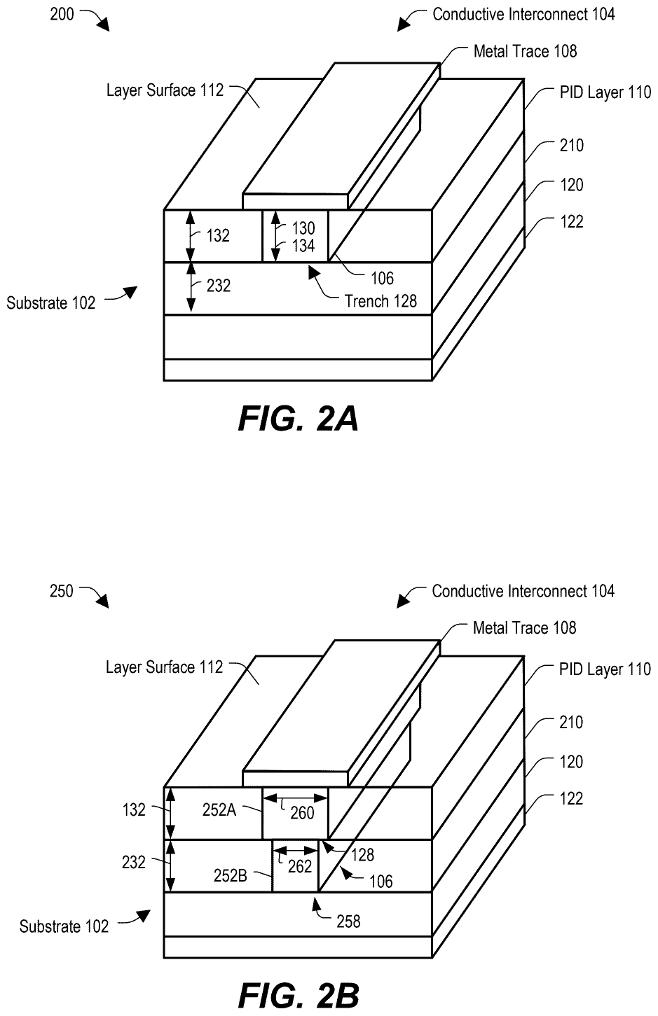

As described in further detail with reference to FIGS. 6A-B, the opening 126 of the trench 128 is defined by a photoimaging process, and a depth 130 of the trench 128 is based on a PID development time. The dimensions of the trench 128 can be designed based on one or more thermal or resistivity criteria associated with the conductive interconnect 104. As illustrated, the depth 130 of the trench 128 is less than a thickness 132 of the PID layer 110. The embedded conductor 106 fills (or substantially fills) the trench 128 so that the thickness 134 of the embedded conductor 106 matches (e.g., equals) the depth 130 of the trench 128. In other implementations, the trench 128 extends to the bottom surface of the PID layer 110 so that the depth 130 of the trench 128 matches the thickness 132 of the PID layer 110, such as described with reference to FIG. 2A.

Although two sidewalls 140 are illustrated as extending substantially vertically from the layer surface 112 to a bottom surface 142 of the trench 128, it should be understood that the trench 128 may be formed having one or more additional sidewalls 140, in accordance with a design geometry of the conductive interconnect 104. Further, although the substrate 102 is illustrated as including a single PID layer 110, in other implementations the substrate 102 includes one or more additional PID layers, and the conductive interconnect 104 extends into one or more trenches of the additional PID layers, such as described in further detail with reference to FIGS. 2B-4B.

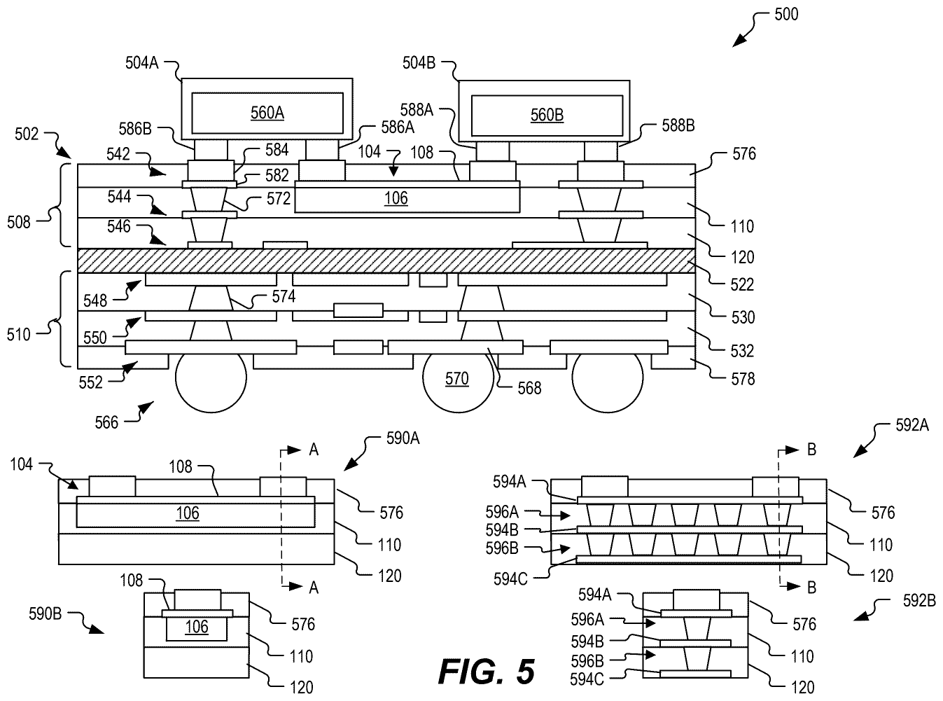

According to an aspect, the conductive interconnect 104 is implemented at an M1 layer, and one or more electronic devices, such as a power amplifier, can be electrically connected to the conductive interconnect 104. The metal in the embedded conductor 106 effectively increases the mass of the M1 layer, providing electrical and thermal benefits that are comparable to or greater than those provided using a conventional via stitching arrangement, such as described in further detail with reference to FIG. 5. For example, as described further with reference to FIG. 5, the use of the additional metal at the M1 layer to replace a stitched via arrangement enables less metal to be used at M2 and M3 layers, freeing space at the M2 and M3 layers for routing and increasing design flexibility.

In addition to the electrical and thermal benefits and improved design flexibility described above, additional benefits may be obtained by using the conductive interconnect 104 instead of a conventional stitched via arrangement. One such benefit can include a reduction or elimination of the use of capture pads that are used with the stitched via arrangement for ensuring robust electrical connections between vias and metal traces. Another benefit can include reducing a laser shot count associated with creating vias of the stitched via arrangement. Thus, a manufacturing time, complexity, and/or cost can be reduced as compared to using a conventional stitched via arrangement.

FIG. 2A illustrates a cross-sectional view of a particular implementation of an exemplary device having an interconnect that includes an embedded conductor within a PID layer, where a thickness of the embedded conductor matches a thickness of the PID layer. The device 200 of FIG. 2A includes many of the same components and features as are described above with reference to FIGS. 1A-B.

In the example shown in FIG. 2A, the substrate 102 includes a second layer 210 (e.g., a dielectric layer, such as a second PID layer) that has a thickness 232 and that is under the PID layer 110, and the embedded conductor 106 extends through the PID layer 110 to an upper surface of the second layer 210. As illustrated, the depth 130 of the trench 128 matches the thickness 132 of the PID layer 110, and the thickness 134 of the embedded conductor 106 also matches the depth 130 of the trench 128.

As compared to FIGS. 1A-1B, in which the depth 130 of the trench 128 can be controlled based on a partial development process (e.g., using a predetermined development time in a chemical bath to control the depth 130 of the trench 128), the trench 128 in FIG. 2A can be formed using a full development process in which the depth 130 of the trench 128 may be controlled based on an etch stop at the upper surface of the second layer 210.

FIG. 2B illustrates a cross-sectional view of another particular implementation of an exemplary device having an interconnect that includes an embedded conductor extending across multiple PID layers. The device 250 of FIG. 2B includes many of the same components and features as are described above with reference to FIGS. 1A-2A.

In the example shown in FIG. 2B, the second layer 210 is a second PID layer defining a second trench 258 under the trench 128 of the PID layer 110, and the embedded conductor 106 extends through the trench 128 and into the second trench 258. In particular, the embedded conductor 106 includes a first portion 252A in the trench 128 of the PID layer 110 and a second portion 252B in the second trench 258 of the second layer 210.

As illustrated, the depth of the second trench 258 matches the thickness 232 of the second PID layer 210. The second trench 258 may be formed in a similar manner as described for the trench 128 in FIG. 2A, such as using a full development process in which the depth of the second trench 258 is controlled based on an etch stop at the upper surface of the layer 120 that is under the second layer 210.

The trench 128 has a first width 260, and the second trench 258 has a second width 262 that is different from the first width 260. As illustrated, the first width 260 is larger than the second width 262. However, in other implementations, the second width 262 may be larger than the first width 260, or the second width 262 may match (e.g., be equal to) the first width 260.

Extending the embedded conductor 106 through multiple PID layers enables a larger amount of metal to be used for the conductive interconnect 104, providing lower resistance and better heat sink capacity as compared to embodiments in which the conductive interconnect 104 does not extend below the PID layer 110.

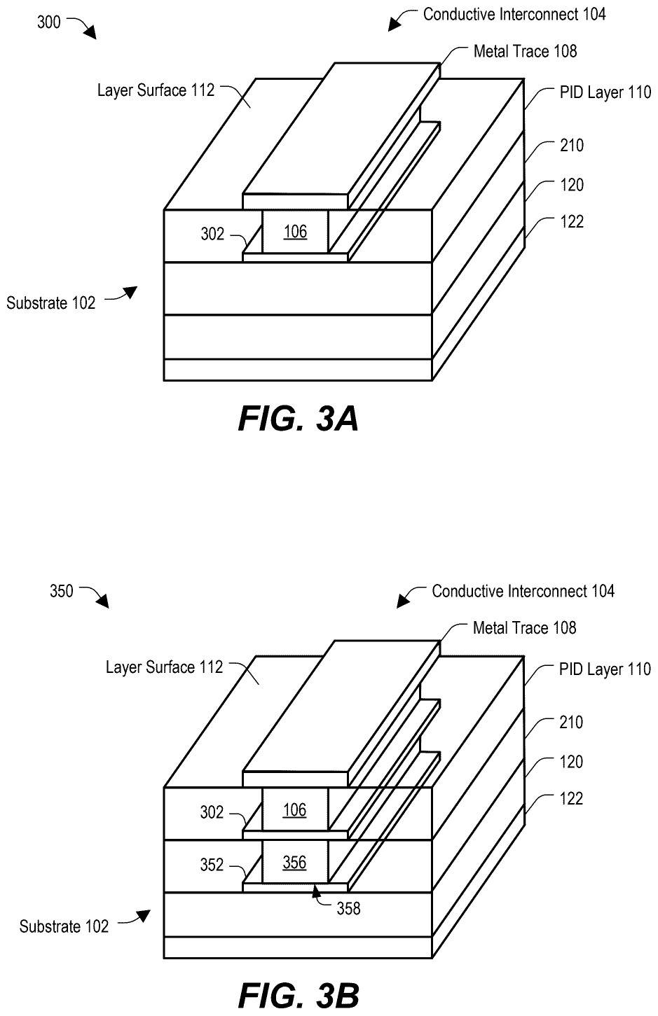

FIG. 3A illustrates a cross-sectional view of another particular implementation of an exemplary device having an interconnect that includes an embedded conductor within a PID layer. The device 300 of FIG. 3A includes many of the same components and features as are described above with reference to FIGS. 1A-2B.

In the example shown in FIG. 3A, the substrate 102 includes the second layer 210 (e.g., a dielectric layer, such as a second PID layer) that is under the PID layer 110. The conductive interconnect 104 further includes a second metal trace 302 on an upper surface of the second layer 210 and between the PID layer 110 and the dielectric layer 210. The second metal trace 302 is electrically connected to the embedded conductor 106. The conductive interconnect 104 is thus formed of the metal trace 108, the embedded conductor 106, and the second metal trace 302.

FIG. 3B illustrates a cross-sectional view of another particular implementation of an exemplary device having an interconnect that includes embedded conductors within multiple PID layers. The device 350 of FIG. 3B includes many of the same components and features as are described above with reference to FIGS. 1A-3A.

In the example shown in FIG. 3B, the embedded conductor 106 extends from the metal trace 108 at the layer surface 112 to the second metal trace 302 at the upper surface of the second layer 210. The second layer 210 is a second PID layer that defines a second trench 358, which extends between the second metal trace 302 and a third metal trace 352 that is at an upper surface of the layer 120. A second embedded conductor 356 is within the second trench 358 and forms an electrical connection between the second metal trace 302 and the third metal trace 352. The conductive interconnect 104 is thus formed of the metal trace 108, the embedded conductor 106, the second metal trace 302, the second embedded conductor 356, and the third metal trace 352.

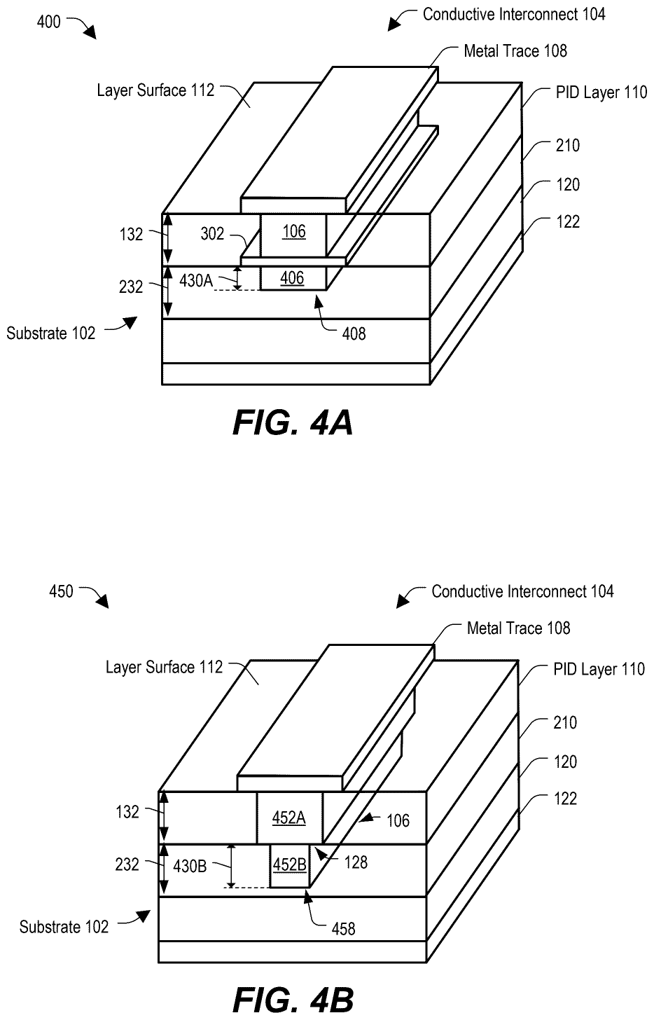

FIG. 4A illustrates a cross-sectional view of a particular implementation of an exemplary device having an interconnect that includes an embedded conductor within a PID layer, where a thickness of the embedded conductor is less than a thickness of the PID layer. The device 400 of FIG. 4A includes many of the same components and features as are described above with reference to FIGS. 1A-3B.

In the example shown in FIG. 4A, the embedded conductor 106 extends from the metal trace 108, through the PID layer 110, to the second metal trace 302. The second layer 210 is a second PID layer, and an embedded conductor 406 is within a trench 408 of the second layer 210 and electrically connected to the second metal trace 302. The conductive interconnect 104 is thus formed of the metal trace 108, the embedded conductor 106, the second metal trace 302, and the embedded conductor 406.

A depth 430A of the trench 408 is less than the thickness 232 of the second layer 210. The depth 430A of the trench 408, and thus the thickness of the embedded conductor 406 in the second layer 210, can be controlled based on a partial development process (e.g., controlling a development time in a chemical bath to control the depth 430A).

FIG. 4B illustrates a cross-sectional view of another particular implementation of an exemplary device having an interconnect that includes an embedded conductor extending through a PID layer and through a portion of another PID layer. The device 450 of FIG. 4B includes many of the same components and features as are described above with reference to FIGS. 1A-4A.

In the example shown in FIG. 4B, the second layer 210 is a second PID layer defining a second trench 458 under the trench 128 of the PID layer 110, and the embedded conductor 106 extends into the second trench 458. In particular, the embedded conductor 106 includes a first portion 452A in the trench 128 of the PID layer 110 and a second portion 452B in the second trench 458 of the second layer 210. The conductive interconnect 104 is thus formed of the metal trace 108 and the portions 452A and 452B of the embedded conductor 106.

A depth 430B of the second trench 458 is less than the thickness 232 of the second layer 210. The depth 430B of the second trench 458, and thus the thickness of the second portion 452B of the embedded conductor 106 in the second layer 210, can be controlled based on a partial development process (e.g., controlling a development time in a chemical bath to control the depth 430B).

As illustrated, a first width of the first trench 128 and the first portion 452A of the embedded conductor 106 is larger than a second width of the second trench 458 and the second portion 452B of the embedded conductor 106. However, in other implementations, the second width may be larger than the first width, or the second width may match (e.g., be equal to) the first width.

Although FIGS. 1A-4B illustrate implementations of devices in which the conductive interconnect 104 extends into, or through, one or two PID layers, in other embodiments the substrate 102 may include three or more PID layers through which the conductive interconnect 104 extends. Although FIGS. 1A-4B describe examples in which the metal trace 108 corresponds to an M1 layer, in other embodiments the conductive interconnect 104 can instead be implemented at an M2 or lower metal layer of the substrate 102.

Exemplary IC Device Having an Interconnect that Includes an Embedded Conductor within a PID Layer

FIG. 5 illustrates a cross-sectional profile view of an exemplary device 500 having an interconnect that includes an embedded conductor within a PID layer. One or more dies, illustrated as a die 504A and a die 504B, are electrically connected to conductors of the substrate 102. In particular, the die 504A and the die 504B are each electrically connected to the conductive interconnect 104 and are further electrically connected to off-package contacts 566 (e.g., contacts of a ball grid array (BGA)) via the conductors of the substrate 102.

The die 504A includes one or more electronic components 560A, and the die 504B includes one or more electronic components 560B. The components 560A, the components 560B, or both, can include a plurality of transistors, filters, mixers, diplexers, multiplexors, and/or other radiofrequency (RF) components or circuit elements. According to an aspect, the die 504A includes or corresponds to a power amplifier, and the die 504B includes one or more antennas or other components of a RF front-end system that operates in conjunction with the power amplifier.

The electronic components 560A are electrically connected to a set of contacts 586 including a contact 586A and a contact 586B of the die 504A. The contacts 586 are configured to be electrically connected, via conductors of the substrate 502, to one or more other dies, to off-package devices by way of the off-package contacts 566, or combinations thereof. As illustrated, the contact 586B is configured to be electrically connected to the off-package contacts 566, and the contact 586A is configured to be electrically connected to die 504B via the conductive interconnect 104.

The electronic components 560B are electrically connected to a set of contacts 588 including a contact 588A and a contact 588B of the die 504B. The contacts 588 are configured to be electrically connected, via conductors of the substrate 502, to one or more other dies, to off-package devices by way of the off-package contacts 566, or combinations thereof. As illustrated, the contact 588B is configured to be electrically connected to the off-package contacts 566, and the contact 588A is configured to be electrically connected to die 504A via the conductive interconnect 104.

The substrate 102 includes a core 522 (e.g., corresponding to or including the core layer 122), an upper laminate stack 508, and a lower laminate stack 510. The upper laminate stack 508 is coupled to a top surface of the core 522. The upper laminate stack 508 includes a set of upper metal layers (e.g., an M1 layer 542, an M2 layer 544, and an M3 layer 546) separated by upper dielectric layer(s) including the PID layer 110 and the layer 120. In the example illustrated in FIG. 5, the M3 layer 546 is directly in contact with the top surface of the core 522. The upper laminate stack 508 also includes interconnections (e.g., conductive vias 572) between the metal layers and through the dielectric layer(s). Although FIG. 1 illustrates the upper laminate stack 508 as including three metal layers and two dielectric layers therebetween, in some implementations, the set of upper metal layers can include more than or fewer than three metal layers, and dielectric layers therebetween.

The upper laminate stack 508 also includes a set of contact pads (e.g., a contact pad 582 in the M1 layer 542) configured to electrically connect the die 504A to conductive paths defined by the set of upper metal layers. For example, in FIG. 1, the contact pad 582 is electrically connected to the contact 586B of the die 504A via a bump pad 584 that extends through a solder resist layer 576 of the upper laminate stack 508. The contact pad 582 is also connected to a pad of the M2 layer 544 by a conductive via 572. The pad of the M2 layer 544 is electrically connected to one of the off-package contacts 566 by way of one or more other conductive vias 572 and pads through the upper laminate stack 508, one or more conductive paths through the core 522, and one or more conductive vias 574 and pads through the lower laminate stack 510.

The lower laminate stack 510 is coupled to a bottom surface of the core 522. The lower laminate stack 510 includes a set of lower metal layers (e.g., an M4 layer 548, an M5 layer 550, and an M6 layer 552) separated by dielectric layers (e.g., a dielectric layer 530 and a dielectric layer 532). In the example illustrated in FIG. 1, the M4 layer 548 is directly in contact with the bottom surface of the core 522. The lower laminate stack 510 also includes interconnections (e.g., conductive vias 574) between the metal layers and through the dielectric layer(s). Although FIG. 1 illustrates the lower laminate stack 510 as including three metal layers and two dielectric layer therebetween, in some implementations, the set of lower metal layers can include more than or fewer than three metal layers, and dielectric layers therebetween.

The lower laminate stack 510 also includes a set of contact pads (e.g., a contact pad 568 in the M6 layer 552) configured to electrically connect the substrate 502 and/or components coupled thereto (e.g., the die 504A) to off-package device(s) via the off-package contacts 566. For example, in FIG. 1, the contact pad 568 is electrically connected to a ball grid array contact 570 of the off-package contacts 566 that extends through a solder resist layer 578 of the lower laminate stack 510. The contact pad 568 is also electrically connected to a pad of the M5 layer 550 and of the M4 layer by conductive vias 574.

Thus, the substrate 502 includes a plurality of metal layers and dielectric layers interposed between the metal layers, the PID layer 110 is one of the dielectric layers, and the metal layers include multiple electrical interconnects including the conductive interconnect 104. The device 500 also includes electronic devices, such as the die 504A and the die 504B, that are electrically connected to the conductive interconnect 104.

A diagram 590A illustrates a cross-sectional profile view of the conductive interconnect 104. The conductive interconnect 104 corresponds to the M1 layer 542, with the metal trace 108 formed in the M1 layer 542 and the embedded conductor 106 electrically connected to the metal trace 108. A diagram 590B illustrates a cross-sectional view of the conductive interconnect 104 along the direction A-A in the diagram 590A.

For purposes of comparison, a diagram 592A illustrates a cross-sectional profile view of a hypothetical device in which the conductive interconnect 104 has been replaced with a conventional three-layer stitched via arrangement. The three-layer stitched via arrangement includes a trace 594A in the M1 layer 542, a trace 594B in the M2 layer 544, and a trace 594C in the M3 layer 546. A set of vias 596A electrically interconnect the trace 594A to the trace 594B, and a set of vias 596B electrically interconnect the trace 594B to the trace 594C. A diagram 592B illustrates a cross-sectional view of the three-layer stitched via arrangement along the direction B-B in the diagram 592A.

According to an aspect, a conductive cross-section of the embedded conductor 106, depicted in the diagram 590B, is greater than a conductive cross-section of the three-layer stitched via arrangement depicted in the diagram 592B. As a result, the embedded conductor 106 has a resistance that is lower than a resistance of the three-layer stitched via arrangement. In addition, the embedded conductor 106 has a thermal conductivity that is higher than the thermal conductivity of the three-layer stitched via arrangement.

The conductive interconnect 104 may therefore provide advantages over the conventional stitched via arrangement, such as by providing increased metal loading, such as in a power output pattern, to satisfy a maximum current criterion, for thermal improvement (e.g., improved heat sinking) and for reduced resistance. Another advantage is reduced metal on lower metal layers (e.g., the M2 layer 544 and the M3 layer 546) for improved design flexibility. A laser via shot count associated with forming the vias 596 of the conventional stitched via arrangement is removed, and a manufacturing cost and/or manufacturing lead time of the substrate 502 may also be reduced. Such advantages may be further enhanced in applications with demanding thermal requirements, such as consumer and automotive applications, and RF and/or analog packages having footprints requiring efficient thermal paths for high-frequency operation.

According to an aspect, by providing a larger volume of copper in the embedded conductor 106 than is achievable using via stitching on a power out pattern for one or more of the dies 504, the conductive interconnect 104 provides an improved heat sink to reduce the operating temperature, lowers electric resistance, improves RF performance, and reduces power consumption. The conductive interconnect 104 may also provide a higher reliability of the metal pattern as compared to the stitched via arrangement. Reducing the via count associated with the stitched via arrangement can also lower a manufacturing cost of the substrate 502 as compared to using a laser blind via process to fabricate the stitched via arrangement.

According to an aspect, the conductive interconnect 104 includes a depth controlled embedded pattern that can be created using standard substrate fabrication processes to provide a thermal path, such as for a power amplifier die. A metal volume on a power output pattern can be increased to reduce the temperature and/or resistance and may therefore improve the RF performance in a RF front-end application.

Although the conductive interconnect 104 is illustrated as having the configuration depicted in FIG. 1, it should be understood that the conductive interconnect 104 may instead have any of the other configurations described with reference to FIGS. 2A-4B. For example, in some embodiments the conductive interconnect 104 further includes an embedded conductor within the layer 120 (e.g., a PID layer), and/or within one or more additional PID layers of the substrate 502.

Although the conductive interconnect 104 is illustrated as a die-to-die interconnection, in other implementations one or more conductive interconnects 104 may be used for one or more other electrical connections, such as for a power supply or ground line, or an input/output connection, as illustrative, non-limiting examples, instead of or in addition to die-to-die interconnection.

Although described as components associated with a RF front-end, in other implementations one or more of the dies 504 may include or correspond to one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the dies 504. Additionally, or alternatively, one or more of the dies 504 may include or operate as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof.

Any of the conductive interconnects and contacts described herein can include, for example, microbumps, conductive pillars, conductive pads (e.g., for pad to pad bonding), or other similar chiplet-to-chiplet interconnect contacts used for three-dimensional (3D) chiplet stacking.

It should be understood that the device 500 may include additional components, other components, fewer components, or a combination thereof, to support the functionality described herein. As non-limiting examples, the device 500 may include additional IC devices, additional layers, additional dies, additional packages, additional interconnects, additional structures, other components, different components, or a combination thereof, to support the functionality and technical advantages disclosed herein.

In some implementations, the device 500 can be integrated in a smartphone, a tablet computer, a fixed location terminal device, an automobile, a wearable electronic device, a laptop computer, or some combination thereof, as described in more detail below with reference to FIG. 8.

While FIG. 5 illustrates an example device that includes the conductive interconnect 104, in other examples, one or more additional integrated devices, packages, or some combination thereof can be present in an integrated circuit without departing from the scope of the subject disclosure. Further, the conductive interconnect 104 can be integrated with or included within a wide variety of other devices. For example, a device that includes one or more of the conductive interconnects 104 disclosed herein can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the conductive interconnect 104 can be used with any of these components (or a combination of these components) that includes active circuitry.

Exemplary Sequences for Fabricating a Device/IC Device Having an Interconnect that Includes an Embedded Conductor within a PID Layer

In some implementations, fabricating a device including any of the devices of FIGS. 1-5 includes several processes. FIGS. 6A and 6B illustrate exemplary sequences for fabricating or providing a device having an interconnect that includes an embedded conductor within a PID layer, as described with reference to any of FIGS. 1-5. In some implementations, the sequences of FIGS. 6A and 6B may be used to provide (e.g., during fabrication of) one or more of the device 100 of FIGS. 1A-B, the device 200 of FIG. 2A, the device 250 of FIG. 2B, the device 300 of FIG. 3A, the device 350 of FIG. 3B, the device 400 of FIG. 4A, the device 450 of FIG. 4B, or the device 500 of FIG. 5.

It should be noted that the sequences of FIGS. 6A and 6B may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 6A and 6B. Each of the various stages of the sequences illustrated in FIGS. 6A-6B shows one or more devices being formed. In other implementations, a single device may be formed or a plurality of devices can be formed concurrently.

FIG. 6A depicts a sequence 600 in which conductive interconnects are formed including embedded conductors within fully developed trenches of PID layers. Stage 1 of FIG. 6A illustrates a state after a PID layer 608 has been formed on an upper surface of a substrate core 602 and a PID layer 612 has been formed on a lower surface of the substrate core 602. The substrate core 602 includes an inner core layer 604, a dielectric layer 606 above the inner core layer 604, and a dielectric layer 610 below the inner core layer 604. The substrate core 602 includes multiple through-core electrical connectors that each include a conductor 620 that extends through the inner core layer 604 and electrically connects to metal pads 622 within the dielectric layer 606 and the dielectric layer 610.

For example, as part of Stage 1, the substrate core 602 may be formed by performing a laser drilling process to form holes through the inner core layer 604. The inner core layer 604 may correspond to a core layer having copper applied to an upper and lower surface. A seed layer can be applied to the inner core layer 604, and a dry film masking and lithography process may be performed, followed by a metal plating process, to form the conductors 620 and the metal pads 622. After removal of the dry film, a lamination process may be used to apply the PID layers 608 and 612 to the upper and lower surfaces, respectively, of the substrate core 602. In a particular embodiment, the PID layer 608, the dielectric layer 606, and the inner core layer 604 correspond to the PID layer 110, the dielectric layer 120, and the core layer 122, respectively, of FIG. 1.

Stage 2 illustrates a state after trenches 630 have been formed in the PID layers 608 and 612. For example, as part of Stage 2, a photoimaging process can be performed to define the openings of the trenches 630 in outer layer surfaces 634 of the PID layers 608 and 612. For example, a mask pattern of the trench openings may be applied to selectively prevent exposure of portions of the PID layers 608 and 612 that correspond to the trenches 630. A PID develop process is performed to form the trenches 630 by removing the unexposed PID material. In some implementations, the PID develop process includes immersion of the device in a chemical bath, which enables more accurate control of the PID develop, and thus more accurate control over the depth of the trenches 630, as compared to using a spray-type PID develop mechanism. After performing the PID develop process, a PID thermal cure process is performed.

As illustrated, the trenches 630 are fully developed, such that the sidewalls 632 of the trenches 630 extend from the layer surfaces 634 to contact the metal pads 622 and/or the dielectric layers 606, 610. In a particular embodiment, a trench 630 corresponds to the trench 128 of FIG. 2A.

Stage 3 illustrates a state after a desmear process has been performed and a seed layer 640 is applied to the layer surfaces 634, the sidewalls 632, and the bottom surfaces of the trenches 630 (e.g., the exposed portions of the metal pads 622 at the bottom of the trenches 630). The desmear process increases the roughness of the exposed PID layer surfaces, such as by removing some resin material of the PID layer surfaces to improve adhesion of the seed layer 640. The seed layer 640 can include a thin layer of plated, sputtered, or evaporated metal that is used to improve a quality of a subsequent metal plating process.

Stage 4 illustrates a state after a dry film formation, exposure, and develop process has been performed. For example, as part of Stage 4, dry film layers 650 are applied (e.g., laminated) to an upper surface of the PID layer 608 and to a lower surface of the PID layer 612. A mask pattern is applied to selectively expose portions of the dry film layers 650, and a dry film develop process removes portions of the dry film layers 650 to form a pattern for metal plating.

Stage 5 illustrates a state after a metal plating process has been performed and the patterned dry film layers have been removed. For example, as part of Stage 5, a fill plating process, such as a copper via fill plating process, is performed to form conductive interconnects 670 that include embedded conductors 672 within the trenches 630 and metal traces 674 that are formed on the embedded conductors 672 and surrounding portions of the layer surfaces 634. The embedded conductors 672 and metal traces 674 are formed via deposition of metal (e.g., copper) onto exposed portions of the seed layer 640, which is not shown in Stage 5. Although the embedded conductors 672 and metal traces 674 are illustrated as distinct components of the conductive interconnects 670, in accordance with some aspects, an embedded conductor 672 and its respective metal trace 674 are formed as a continuous metal component during the fill plating process. After plating, the dry film layers 650 are removed, such as by a stripping operation, and an etching process is performed to remove remaining portions of the seed layer 640 that are exposed due to removal of the dry film layers 650.

In a particular embodiment, the conductive interconnect 670 corresponds to the conductive interconnect 104, the embedded conductor 672 corresponds to the embedded conductor 106, and the metal trace 674 corresponds to the metal trace 108 of FIG. 2A.

FIG. 6B depicts a sequence 690 in which conductive interconnects are formed including embedded conductors within partially developed trenches of PID layers. Stage 1 of FIG. 6B matches Stage 1 of FIG. 6A and illustrates a state after the PID layer 608 has been formed on the upper surface of the substrate core 602 and the PID layer 612 has been formed on the lower surface of the substrate core 602.

In a particular embodiment, the PID layer 608, the dielectric layer 606, and the inner core layer 604 correspond to the PID layer 110, the dielectric layer 120, and the core layer 122, respectively, of FIG. 1.

Stage 2 illustrates a state after trenches 692 have been formed in the PID layers 608 and 612. For example, as part of Stage 2, a photoimaging process can be performed to define the openings of the trenches 692 in the outer layer surfaces 634 of the PID layers 608 and 612. For example, a mask pattern of the trench openings may be applied to selectively prevent exposure of portions of the PID layers 608 and 612 that correspond to the trenches 692. A PID partial develop process is performed to form the trenches 692 by removing a portion of the unexposed PID material. In some implementations, the PID partial develop process includes immersion of the device in a chemical bath, and a length of immersion in the chemical bath is monitored to control the depth of the trenches 692. After performing the PID partial develop process, a PID thermal cure process is performed.

As illustrated, the trenches 692 are partially developed, such that the sidewalls 693 of the trenches 692 do not extend to the metal pads 622 and/or the dielectric layers 606, 610. In a particular embodiment, a trench 692 corresponds to the trench 128 of FIG. 1 or the trench 408 of FIG. 4A.

Stage 3 illustrates a state after a desmear process has been performed and the seed layer 640 is applied to the layer surfaces 634, the sidewalls 693, and the bottom surfaces of the trenches 692. The desmear process increases the roughness of the exposed PID layer surfaces, such as by removing some resin material of the PID layer surfaces to improve adhesion of the seed layer 640. The seed layer 640 can include a thin layer of plated, sputtered, or evaporated metal that is used to improve a quality of a subsequent metal plating process.

Stage 4 illustrates a state after a dry film formation, exposure, and develop process has been performed. For example, as part of Stage 4, dry film layers 650 are applied (e.g., laminated) to an upper surface of the PID layer 608 and to a lower surface of the PID layer 612. A mask pattern is applied to selectively expose portions of the dry film layers 650, and a dry film develop process removes portions of the dry film layers 650 to form a pattern for metal plating.

Stage 5 illustrates a state after a metal plating process has been performed and the patterned dry film layers have been removed. For example, as part of Stage 5, a fill plating process, such as a copper via fill plating process, is performed to form conductive interconnects 694 that include embedded conductors 696 within the trenches 692 and metal traces 698 that are formed on the embedded conductors 696 and surrounding portions of the layer surfaces 634. The embedded conductors 696 and metal traces 698 are formed via deposition of metal (e.g., copper) onto exposed portions of the seed layer 640, which is not shown in Stage 5. Although the embedded conductors 696 and metal traces 698 are illustrated as distinct components of the conductive interconnects 694, in accordance with some aspects, an embedded conductor 696 and its respective metal trace 698 are formed as a continuous metal component during the fill plating process. After plating, the dry film layers 650 are removed, such as by a stripping operation, and an etching process is performed to remove remaining portions of the seed layer 640 that are exposed due to removal of the dry film layers 650.

In a particular embodiment, the conductive interconnect 694 corresponds to the conductive interconnect 104 of FIG. 1, the embedded conductor 696 corresponds to the embedded conductor 106 of FIG. 1 or the embedded conductor 406 of FIG. 4A, and the metal trace 698 corresponds to the metal trace 108 of FIG. 1 or the metal trace 302 of FIG. 4A.

Although the sequence 600 of FIG. 6A and the sequence 690 of FIG. 6B each depicts formation of conductive interconnects that extend into, or through, a single PID layer, one or more sequences of steps of the sequence 600, the sequence 690, or combinations thereof, may be repeated to form multi-layer conductive interconnects, such as depicted in FIGS. 2B-4B. For example, the device 250 of FIG. 2B can be formed using Stages 1-5 of FIG. 6A to form the trench 258 and the portion 252B of the embedded conductor 106 within the trench 258 (without also forming the trace 674 during the metal fill process of Stage 5), followed by repeating Stages 1-5 of FIG. 6A to form the trench 128, the portion 252A of the embedded conductor 106 within the trench 128, and the metal trace 108. Alternatively, the device 250 of FIG. 2B can be formed using Stages 1-2 of FIG. 6A to form the trench 258, followed by Stages 1-5 of FIG. 6A to form the trench 128 above the trench 258. In this example, the metal fill process of Stage 5 fills both of the trench 128 and the trench 258 in addition to forming the metal trace 108.

In another example, the device 350 of FIG. 3B can be formed using Stages 4 and 5 of FIG. 6A to form the metal trace 352 on a surface of the layer 120, followed by performing Stages 1-5 of FIG. 6A to form the embedded conductor 356 and the metal trace 302, followed by repeating Stages 1-5 of FIG. 6A to form the embedded conductor 106 and the metal trace 108 of FIG. 3B.

In another example, the device 400 of FIG. 4A can be formed using Stages 1-5 of FIG. 6B to form the partially developed trench 408, the embedded conductor 406 in the partially developed trench 408, and the metal trace 302, followed by Stages 1-5 of FIG. 6A to form the trench 128, the embedded conductor 106 within the trench 128, and the metal trace 108 of FIG. 4A.

In another example, the device 450 of FIG. 4B can be formed using Stages 1-5 of FIG. 6B to form the partially developed trench 458 and the portion 452B of the embedded conductor 106 within the trench 458 (without also forming the trace 698 during the metal fill process of Stage 5), followed by Stages 1-5 of FIG. 6A to form the fully developed trench 128, the portion 452A of the embedded conductor 106 within the trench 128, and the metal trace 108. Alternatively, the device 450 of FIG. 4B can be formed using Stages 1-3 of FIG. 6B to form the partially developed trench 458, followed by Stages 1-5 of FIG. 6A to form the fully developed trench 128 above the trench 458. In this example, the metal fill process of Stage 5 fills both of the trench 128 and the trench 458 in addition to forming the metal trace 108.

Although certain Stages are illustrated in FIGS. 6A and 6B, other processes can be included in the fabrication of devices having conductive interconnects including embedded conductors in PID layers without departing from the scope of the subject disclosure.

Exemplary Flow Diagram of a Method for Fabricating a Device/Integrated Device Having an Interconnect that Includes an Embedded Conductor within a PID Layer

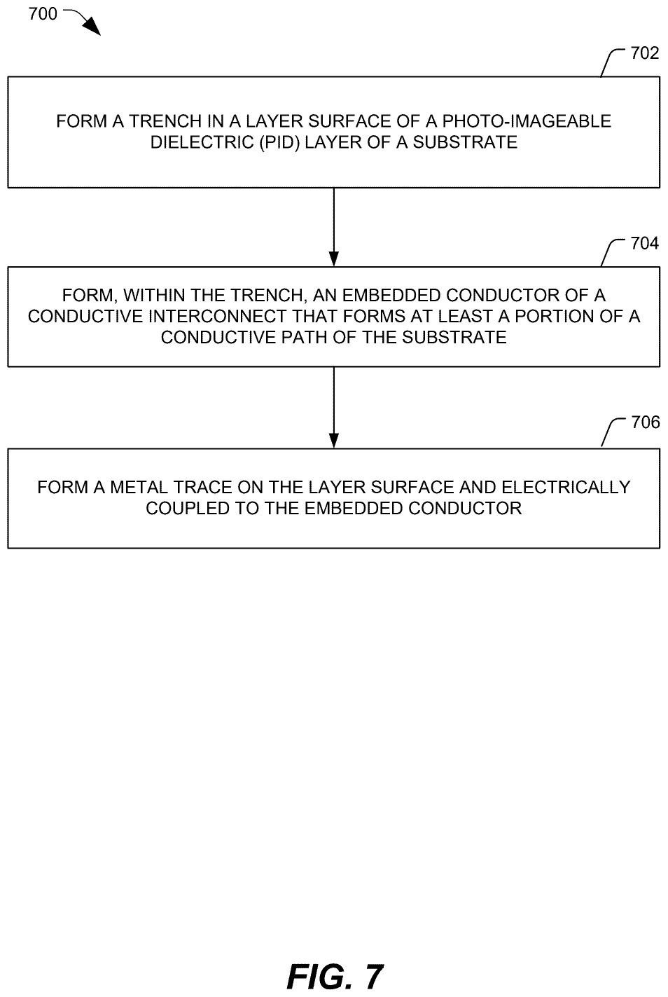

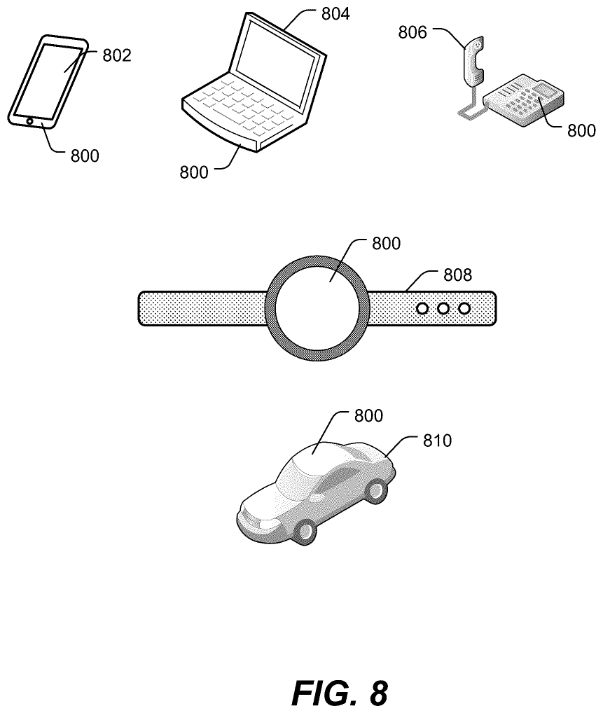

In some implementations, fabricating a device having an interconnect that includes an embedded conductor within a PID layer includes several processes. FIG. 7 illustrates an exemplary flow diagram of a method 700 of fabricating an illustrative device that includes an interconnect that includes an embedded conductor within a PID layer. In a particular aspect, one or more operations of the method 700 are performed by one or more processors of a fabrication system. In some implementations, operations of the method 700 may be stored as instructions by a non-transitory computer-readable storage medium, and the instructions may be executable by at least one processor to cause the at least one processor to perform operations of the method 700. In some implementations, the method 700 of FIG. 7 may be used to provide or fabricate any of the devices FIGS. 1-5.

It should be noted that the method 700 of FIG. 7 may combine one or more processes in order to simplify and/or clarify the method for providing or fabricating an integrated circuit device. In some implementations, the order of the processes may be changed or modified.

The method 700 includes forming a trench in a layer surface of a photo-imageable dielectric (PID) layer of a substrate, at block 702. For example, each of Stage 2 of FIG. 6A and Stage 2 of FIG. 6B illustrates and describes an example of forming a trench in the layer surface 634 of the PID layer 608. In some implementations, an opening of the trench is defined by a photoimaging process, and a depth of the trench is based on a PID development time. For example, Stage 2 of FIG. 6B illustrates and describes examples of defining an opening of the trench by a photoimaging process and controlling a depth of the trench based on a PID develop time. The trench of the method 700 can include the trench 128 of FIGS. 1A-4B, the trench 258 of FIG. 2B, the trench 358 of FIG. 3B, the trench 408 of FIG. 4A, or the trench 458 of FIG. 4B, as illustrative, non-limiting examples.

The method 700 includes forming, within the trench, an embedded conductor of a conductive interconnect that forms at least a portion of a conductive path of the substrate, at block 704. In a particular embodiment, forming the embedded conductor includes performing a fill plating process. For example, Stages 3-5 of FIG. 6A and stages 3-5 of FIG. 6B illustrate and describe examples of forming embedded conductors within a trench of the PID layer 608. The embedded conductor of the method 700 can include the embedded conductor 106 of FIGS. 1A-4B, the embedded conductor 356 of FIG. 3B, or the embedded conductor 406 of FIG. 4A, as illustrative, non-limiting examples.

The method 700 includes forming a metal trace on the layer surface and electrically coupled to the embedded conductor, at block 706. For example, Stages 3-5 of FIG. 6A and stages 3-5 of FIG. 6B illustrate and describe examples of forming metal traces on the layer surface of the PID layer 608 and electrically connected to the embedded conductor. The metal trace of the method 700 can include the metal trace 108 of FIGS. 1A-4B, the metal trace 302 of FIGS. 3A-4A, or the metal trace 352 of FIG. 3B, as illustrative, non-limiting examples.

In some implementations, the method 700 also includes electrically connecting the conductive interconnect to an electronic device. For example, the conductive interconnect 104 of FIG. 5 is electrically connected to the die 504A, the die 504B, or a combination thereof.

### Exemplary Electronic Devices

FIG. 8 illustrates various electronic devices that may integrate an exemplary interconnect that includes an embedded conductor within a PID layer as described herein. For example, a mobile phone device 802, a laptop computer device 804, a fixed location terminal device 806, a wearable device 808, or a vehicle 810 (e.g., an automobile or an aerial device) may include a device 800. The device 800 can include, for example, any of the device 100 of FIGS. 1A-B, the device 200 of FIG. 2A, the device 250 of FIG. 2B, the device 300 of FIG. 3A, the device 350 of FIG. 3B, the device 400 of FIG. 4A, the device 450 of FIG. 4B, the device 500 of FIG. 5 and/or any other integrated device having an exemplary interconnect that includes an embedded conductor within a PID layer as described herein. The devices 802, 804, 806 and 808 and the vehicle 810 illustrated in FIG. 8 are merely exemplary. Other electronic devices may also feature the device 800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-5 may be rearranged and/or combined into a single component, process, feature or function or embodied in several components, processes, or functions. Additional elements, components, processes, and/or functions may also be added without departing from the disclosure. It should also be noted FIGS. 1A-5 and its corresponding description in the present disclosure is not limited to dies and/or ICs. In some implementations, FIGS. 1A-5 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a substrate includes a photo-imageable dielectric (PID) layer having a layer surface and multiple sidewalls extending from an opening in the layer surface to define a trench; and a conductive interconnect configured to form at least a portion of a conductive path of the substrate, the conductive interconnect includes an embedded conductor within the trench; and a metal trace on the layer surface and electrically connected to the embedded conductor.

Example 2 includes the device of Example 1, wherein a depth of the trench is less than a thickness of the PID layer, and wherein a thickness of the embedded conductor matches the depth of the trench.

Example 3 includes the device of Example 1, wherein a depth of the trench matches a thickness of the PID layer, and wherein a thickness of the embedded conductor matches the depth of the trench.

Example 4 includes the device of Example 3, wherein the substrate includes a second PID layer defining a second trench, and wherein the embedded conductor extends into the second trench.

Example 5 includes the device of Example 4, wherein the trench has a first width, and wherein the second trench has a second width that is different from the first width.

Example 6 includes the device of Example 3, wherein the substrate includes a dielectric layer under the PID layer, the conductive interconnect further includes a second metal trace between the PID layer and the dielectric layer, and the second metal trace is electrically connected to the embedded conductor.

Example 7 includes the device of Example 6, wherein the dielectric layer is a second PID layer defining a second trench, and wherein the conductive interconnect further includes a second embedded conductor within the second trench and electrically connected to the second metal trace.

Example 8 includes the device of any of Examples 1 to 7, wherein the substrate comprises a plurality of metal layers and dielectric layers interposed between the metal layers, the PID layer is one of the dielectric layers, and the metal layers include multiple electrical interconnects including the conductive interconnect.

Example 9 includes the device of any of Examples 1 to 8 and further includes an electronic device electrically connected to the conductive interconnect.

Example 10 includes the device of Example 9, wherein the electronic device includes a power amplifier.

Example 11 includes the device of any of Examples 1 to 10, wherein the conductive interconnect corresponds to a first metal layer, and wherein a first conductive cross-section of the embedded conductor is greater than a second conductive cross-section of a three-layer stitched via arrangement.

Example 12 includes the device of any of Examples 1 to 11, wherein the embedded conductor has a first resistance that is lower than a second resistance of a three-layer stitched via arrangement.

Example 13 includes the device of any of Examples 1 to 12, wherein the embedded conductor has a first thermal conductivity that is higher than a second thermal conductivity of a three-layer stitched via arrangement.

According to Example 14, a device includes a substrate includes a photo-imageable dielectric (PID) layer having a layer surface and multiple sidewalls extending from an opening in the layer surface to define a trench; and a conductive interconnect configured to form at least a portion of a conductive path of the substrate, the conductive interconnect includes an embedded conductor within the trench; and a metal trace on the layer surface and electrically connected to the embedded conductor; and an electronic device electrically coupled to the conductive interconnect.

Example 15 includes the device of Example 14, wherein a depth of the trench is less than a thickness of the PID layer, and wherein a thickness of the embedded conductor matches the depth of the trench.

Example 16 includes the device of Example 14, wherein a depth of the trench matches a thickness of the PID layer, and wherein a thickness of the embedded conductor matches the depth of the trench.

Example 17 includes the device of Example 16, wherein the substrate includes a second PID layer defining a second trench, and wherein the embedded conductor extends into the second trench.

Example 18 includes the device of Example 17, wherein the trench has a first width, and wherein the second trench has a second width that is different from the first width.

Example 19 includes the device of Example 16, wherein the substrate includes a dielectric layer under the PID layer, the conductive interconnect further includes a second metal trace between the PID layer and the dielectric layer, and the second metal trace is electrically connected to the embedded conductor.

Example 20 includes the device of Example 19, wherein the dielectric layer is a second PID layer defining a second trench, and wherein the conductive interconnect further includes a second embedded conductor within the second trench and electrically connected to the second metal trace.

Example 21 includes the device of any of Examples 14 to 20, wherein the substrate comprises a plurality of metal layers and dielectric layers interposed between the metal layers, the PID layer is one of the dielectric layers, and the metal layers include multiple electrical interconnects including the conductive interconnect.

Example 22 includes the device of any of Examples 14 to 21 and further includes an electronic device electrically connected to the conductive interconnect.

Example 23 includes the device of Example 22, wherein the electronic device corresponds to a power amplifier, and wherein the conductive interconnect corresponds to a power out line.

Example 24 includes the device of any of Examples 14 to 23, wherein the conductive interconnect corresponds to a first metal layer, and wherein a first conductive cross-section of the embedded conductor is greater than a second conductive cross-section of a three-layer stitched via arrangement.

Example 25 includes the device of any of Examples 14 to 24, wherein the embedded conductor has a first resistance that is lower than a second resistance of a three-layer stitched via arrangement.

Example 26 includes the device of any of Examples 14 to 25, wherein the embedded conductor has a first thermal conductivity that is higher than a second thermal conductivity of a three-layer stitched via arrangement.

Example 27 includes the device of any of Examples 14 to 26, wherein the substrate includes a dielectric layer under the PID layer, the conductive interconnect further includes a second metal trace between the PID layer and the dielectric layer, and the second metal trace is electrically connected to the embedded conductor.

According to Example 28, a method of fabrication includes forming a trench in a layer surface of a photo-imageable dielectric (PID) layer of a substrate; forming, within the trench, an embedded conductor of a conductive interconnect that forms at least a portion of a conductive path of the substrate; and forming a metal trace on the layer surface and electrically coupled to the embedded conductor.

Example 29 includes the method of Example 28, wherein an opening of the trench is defined by a photoimaging process, and wherein a depth of the trench is based on a PID development time.

Example 30 includes the method of Example 28 or Example 29, wherein forming the embedded conductor includes performing a fill plating process.

Example 31 includes the method of any of Examples 28 to 30 and further includes electrically connecting the conductive interconnect to an electronic device.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a substrate comprising:
a photo-imageable dielectric (PID) layer having a layer surface and multiple sidewalls extending from an opening in the layer surface to define a trench; and
a conductive interconnect configured to form at least a portion of a conductive path of the substrate, the conductive interconnect comprising:
an embedded conductor within the trench; and
a metal trace on the layer surface and electrically connected to the embedded conductor.

2. The device of claim 1, wherein a depth of the trench is less than a thickness of the PID layer, and wherein a thickness of the embedded conductor matches the depth of the trench.

3. The device of claim 1, wherein a depth of the trench matches a thickness of the PID layer, and wherein a thickness of the embedded conductor matches the depth of the trench.

4. The device of claim 3, wherein the substrate includes a second PID layer defining a second trench, and wherein the embedded conductor extends into the second trench.

5. The device of claim 4, wherein the trench has a first width, and wherein the second trench has a second width that is different from the first width.

6. The device of claim 3, wherein the substrate includes a dielectric layer under the PID layer, the conductive interconnect further includes a second metal trace between the PID layer and the dielectric layer, and the second metal trace is electrically connected to the embedded conductor.

7. The device of claim 6, wherein the dielectric layer is a second PID layer defining a second trench, and wherein the conductive interconnect further includes a second embedded conductor within the second trench and electrically connected to the second metal trace.

8. The device of claim 1, wherein the substrate comprises a plurality of metal layers and dielectric layers interposed between the metal layers, the PID layer is one of the dielectric layers, and the metal layers include multiple electrical interconnects including the conductive interconnect.

9. The device of claim 1, further comprising an electronic device electrically connected to the conductive interconnect.

10. The device of claim 9, wherein the electronic device includes a power amplifier.

11. The device of claim 1, wherein the conductive interconnect corresponds to a first metal layer, and wherein a first conductive cross-section of the embedded conductor is greater than a second conductive cross-section of a three-layer stitched via arrangement.

12. The device of claim 1, wherein the embedded conductor has a first resistance that is lower than a second resistance of a three-layer stitched via arrangement.

13. The device of claim 1, wherein the embedded conductor has a first thermal conductivity that is higher than a second thermal conductivity of a three-layer stitched via arrangement.

14. A device comprising:
a substrate comprising:
a photo-imageable dielectric (PID) layer having a layer surface and multiple sidewalls extending from an opening in the layer surface to define a trench; and
a conductive interconnect configured to form at least a portion of a conductive path of the substrate, the conductive interconnect comprising:
an embedded conductor within the trench; and
a metal trace on the layer surface and electrically connected to the embedded conductor; and
an electronic device electrically coupled to the conductive interconnect.

15. The device of claim 14, wherein the electronic device corresponds to a power amplifier, and wherein the conductive interconnect corresponds to a power out line.

16. The device of claim 14, wherein the substrate includes a dielectric layer under the PID layer, the conductive interconnect further includes a second metal trace between the PID layer and the dielectric layer, and the second metal trace is electrically connected to the embedded conductor.

17. A method of fabrication comprising:
forming a trench in a layer surface of a photo-imageable dielectric (PID) layer of a substrate;
forming, within the trench, an embedded conductor of a conductive interconnect that forms at least a portion of a conductive path of the substrate; and
forming a metal trace on the layer surface and electrically coupled to the embedded conductor.

18. The method of claim 17, wherein an opening of the trench is defined by a photoimaging process, and wherein a depth of the trench is based on a PID development time.

19. The method of claim 17, wherein forming the embedded conductor includes performing a fill plating process.

20. The method of claim 17, further comprising electrically connecting the conductive interconnect to an electronic device.
